(19) United States
(12) Patent Application Publication
(10) Pub. No.: US 2015/0156924 A1
(43) Pub. Date: Jun. 4, 2015

(54) HEAT CONDUCTIVE PLATE AND HEAT DISSIPATING MODULE USING THE SAME

(71) Applicants: Inventec Corporation, Taipei City (TW); Inventec (Pudong) Technology Corporation, Shanghai (CN)

(72) Inventor: FU-JUNG WU, Taipei City (TW)

(73) Assignees: Inventec Corporation, Taipei City (TW); Inventec (Pudong) Technology Corporation, Shanghai (CN)

(21) Appl. No.: 14/230,104

(22) Filed: Mar. 31, 2014

(30) Foreign Application Priority Data
Nov. 29, 2013 (CN) 201310628317.5

(51) Int. Cl. H05K 7/20; F28D 15/02

(52) U.S. Cl. CPC H05K 7/20336; H05K 7/2039; F28D 15/02

(57) ABSTRACT

The disclosure relates to a heat conductive plate and a heat dissipating module using the same. The heat dissipating module is adapted for dissipating the heat generated by a heat source. The heat dissipating module includes a heat pipe and the heat conductive plate. The carrier unit has a first surface and a second surface opposite to each other. The first surface thermally contacts with the heat pipe. The second surface thermally contacts with the heat source. The extending unit is disposed on the first surface of the carrier unit. The extending unit includes a first extending section. The first extending section extends away from the first surface of the carrier unit.

### CROSS-REFERENCE TO RELATED APPLICATIONS

This non-provisional application claims priority under 35 U.S.C. §119(a) on Patent Application No(s). 201310628317.5 filed in China on Nov. 29, 2013, the entire contents of which are hereby incorporated by reference.

### BACKGROUND OF THE INVENTION

1. Technical Field of the Invention

The disclosure relates to a heat conductive plate and a heat dissipating module comprising the heat conductive plate, and more particularly, to a heat conductive plate and a heat dissipating module comprising the heat conductive plate having a better heat dissipating efficiency.

2. Description of the Related Art

As the performance of electronic components inside electronic devices improved, the power consumed by the electronic components and the heat generated by the electronic components increased. When the heat generated by the electronic components increases, the electronic components lose function or fail because of the temperature inside the electronic devices increases higher than an allowable temperature. Therefore, it is important to improve the heat dissipation of the electronic devices.

### SUMMARY OF THE INVENTION

According to an embodiment, a heat conductive plate for thermally contacting with a heat pipe is disclosed. The heat conductive plate comprises a carrier unit and at least one extending unit. The heat pipe thermally contacts with a surface of the carrier unit. The at least one extending unit is disposed on the surface of the carrier unit. The at least one extending unit comprises a first extending section. The first extending section extends away from the surface of the carrier unit.

According to an embodiment, a heat dissipating module for dissipating the heat generated by a heat source is disclosed. The heat dissipating module comprises a heat pipe and a heat conductive plate. The heat conductive plate comprises a carrier unit and at least one extending unit. The carrier unit has a first surface and a second surface opposite to each other. The first surface thermally contacts with the heat pipe, and the second surface thermally contacts with the heat source. The at least one extending unit is disposed on the first surface of the carrier unit. The at least one extending unit comprises a first extending section. The first extending section extends away from the first surface of the carrier unit.

### BRIEF DESCRIPTION OF THE DRAWINGS

The present disclosure will become more fully understood from the detailed description given hereinbelow, along with the accompanying drawings which are for illustration only, thus are not limitative of the present disclosure, and wherein:

FIG. 1A is a schematic view of a heat conductive plate according to an embodiment of the disclosure;

FIG. 1B is a schematic view of a heat dissipating module according to an embodiment of the disclosure;

FIG. 2A is a schematic view of a heat conductive plate according to another embodiment of the disclosure;

FIG. 2B is a schematic view of a heat dissipating module according to another embodiment of the disclosure;

FIG. 3A is an exploded view of part of an electronic device according to an embodiment of the disclosure;

FIG. 3B is a schematic view of part of an electronic device according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

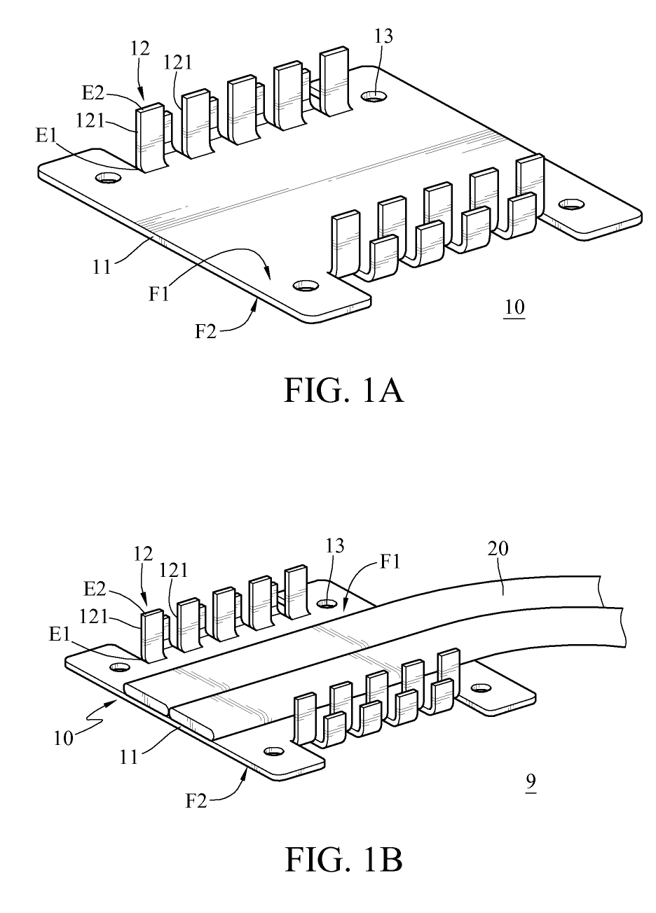

Please refer to FIG. 1A and FIG. 1B. FIG. 1A is a schematic view of a heat conductive plate according to an embodiment of the disclosure. FIG. 1B is a schematic view of a heat dissipating module according to an embodiment of the disclosure. As shown in FIG. 1A, the heat conductive plate 10 of the disclosure comprises a carrier unit 11 and at least one extending unit 12. In FIG. 1A, the quantity of the extending units 12 is two. However, the quantity of the extending units 12 does not limit the disclosure.

The carrier unit 11 has a first surface F1 and a second surface F2 that are opposite to each other. The extending units 12 are disposed on the first surface F1 (i.e., a surface of the carrier unit 11). The extending units 12 are disposed at two opposite sides of the carrier unit 11. Each extending unit 12 has a first extending section 121. The first extending sections 121 extend away from the first surface F1 of the carrier unit 11 towards outside the carrier unit 11. Each first extending section 121 has a first end E1 and a second end E2 opposite to each other. The first ends E1 connect with the first surface F1 of the carrier unit 11. Adjacent first extending sections 121 do not contact with each other and intervals are kept therebetween. Therefore, the heat conductive plate 10 has a greater surface area for heat exchange with air and has a better heat dissipating efficiency. In this embodiment, the carrier unit 11 and the extending units 12 are formed into one piece, but the disclosure is not limited thereto.

As shown in FIG. 1B, the heat dissipating module 9 comprises a heat conductive plate 10 and a heat pipe 20. The first surface F1 of the carrier unit 11 thermally contacts with the heat pipe 20, and the second surface F2 of the carrier unit 11 thermally contacts with a heat source (not shown) for dissipating the heat generated by the heat source.

In this embodiment, the conductive plate 10 is made of metal, so that the heat conductive plate 10 has a better heat conductive ability. For example, the conductive plate 10 is made of metal having a high coefficient of heat dissipation, e.g. copper or aluminum, but the disclosure is not limited thereto.

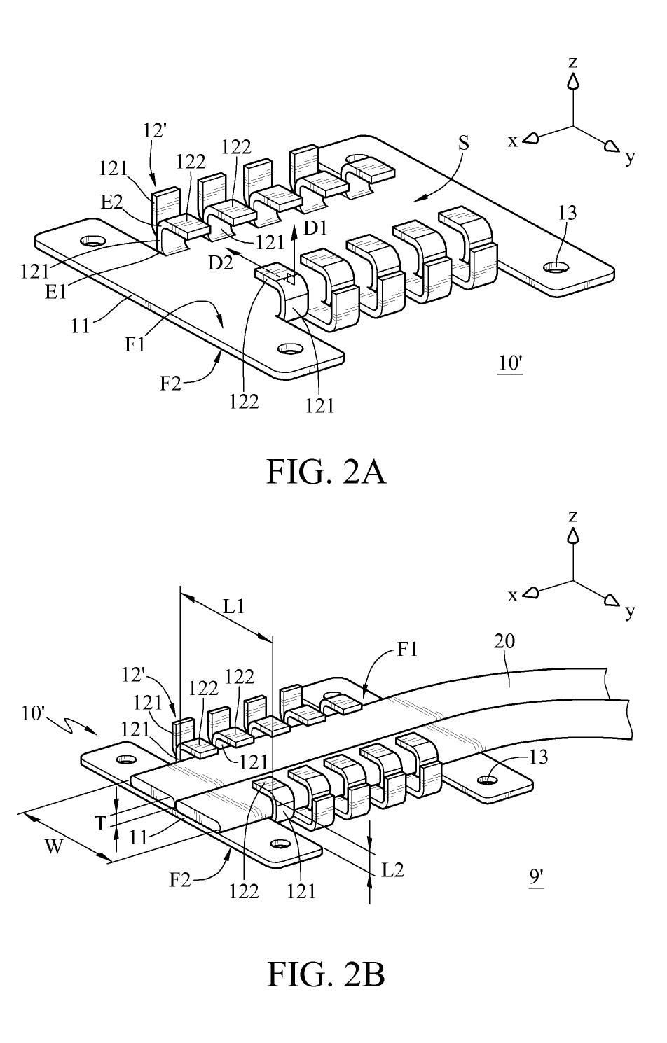

Please refer to FIGS. 2A and 2B. FIG. 2A is a schematic view of a heat conductive plate according to another embodiment of the disclosure. FIG. 2B is a schematic view of a heat dissipating module according to another embodiment of the disclosure. The embodiment of FIGS. 2A and 2B is similar with the embodiment of FIGS. 1A and 1B, wherein identical symbols represent the identical or similar units, so the repeated is not described again.

In this embodiment, the extending section 12′ of the heat conductive plate 10′ further comprises a second extending section 122. The second extending section 122 extends from the second end E2 of the first extending section 121 towards another second extending section 122. The extending direction D2 of the second extending section 122 is substantially parallel to the first surface F1. As shown in FIG. 2A, the extending direction D1 of the first extending section 121 is substantially parallel to the extending direction D2 of the second extending section 122. Therefore, the second extending section 122 and the carrier unit 11 have a space S therebetween, so that a heat pipe 20 is disposed in the space S. Further, the second extending section 122 and the carrier unit 11 can confine the motion of the heat pipe 20 along direction Z.

In this embodiment, the quantity of the extending units 12′ is two, but the disclosure is not limited thereto. The distance L1 between the first extending sections 121 of the extending unit 12′ corresponds to the width W of the heat pipe 20. Thus, two first extending sections 121 are adapted for confining the motion of the heat pipe 20 along direction Y and clamping the heat pipe 20 therebetween. Therefore, the heat pipe 20 is fastened on the carrier unit 11.

Also, the distance L2 between the two second extending sections 122 and the first surface F1 (i.e. the surface of the carrier unit 11) of the surface F1 corresponds to the thickness T of the heat pipe 20. Thus, the heat pipe 20 is clamped between the two second extending sections 122 and is fastened on the carrier unit 11.

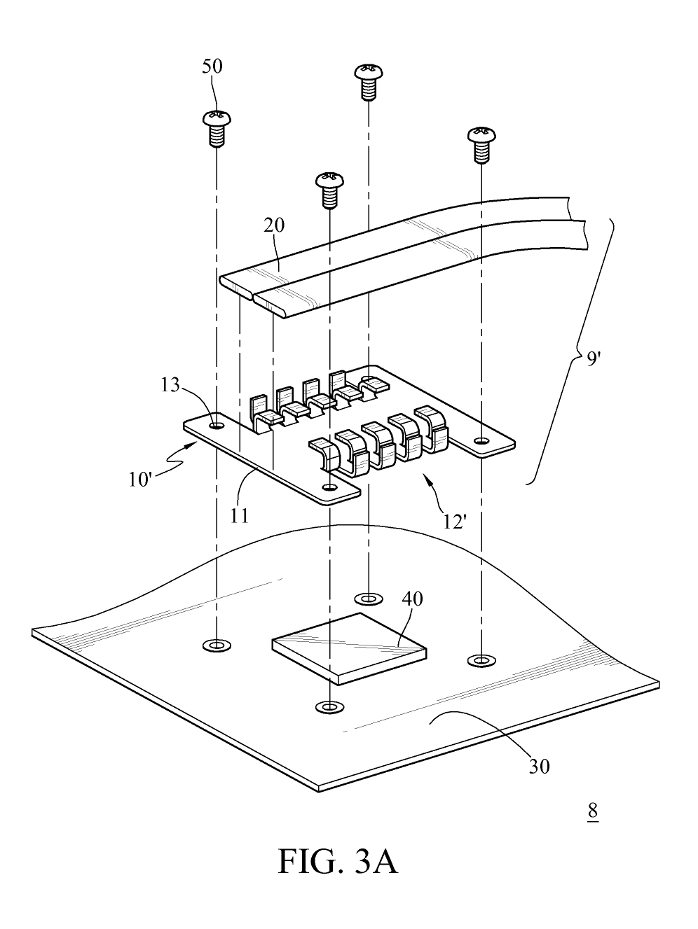

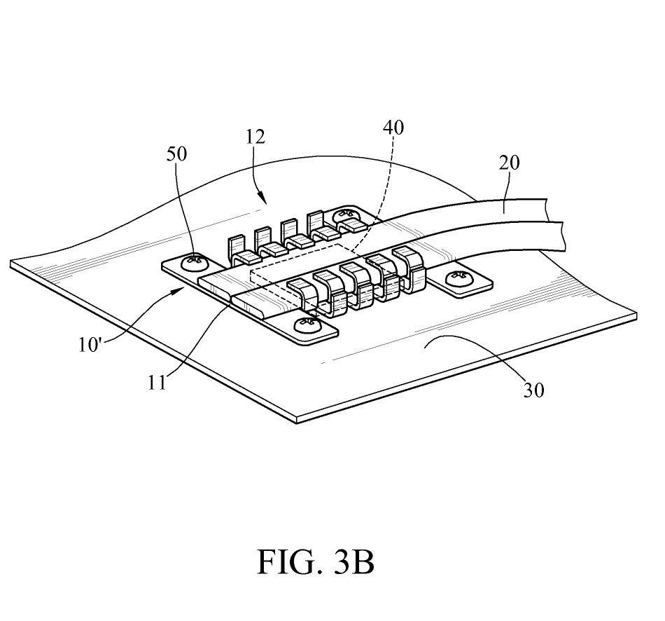

Please refer to FIGS. 3A and 3B. FIG. 3A is an exploded view of part of an electronic device according to an embodiment of the disclosure. FIG. 3B is a schematic view of part of an electronic device according to an embodiment of the disclosure. As shown in the figures, an electronic device 8 comprises a heat conductive plate 10′, a heat pipe 20, a circuit board 30, a heat source 40 and at least one fixing unit 50 (for example, a screw). The combination of the heat conductive plate 10′ and the heat pipe 20 is the heat dissipating module 9′ described in FIG. 2B. The structure and the relative positions of the heat conductive plate 10′ and the heat pipe 20 are described above, so the repeated is not described again. The heat source 40 is disposed on the circuit board 30. The heat source 40 is, for example, an electronic component (e.g. a north bridge chip), but the disclosure is not limited thereto. The heat dissipating module 9′, which is constituted by the heat conductive plate 10′ and the heat pipe 20, is disposed on the circuit board 30. The heat source 40 is clamped between the heat dissipating module 9′ and the circuit board 30. The carrier unit 11 of the heat dissipating module 9′ has at least one fixing hole 13. Therefore, the heat dissipating module 9′ is fixed inside the electronic device 8 by the fixing unit 50 fixed with the fixing hole 13. The electronic device 8 of the embodiment has a better heat dissipating efficiency because the electronic device 8 comprises the heat dissipating module 9′. Therefore, when the performance of the heat source 40 is improved and the heat source consumes more power, the electronic device does not fail or lose function and is capable of maintaining normal operations.

According to the heat conductive plate and the heat dissipating module comprising the heat conductive plate of the disclosure, the first extending section of the extending unit of the heat conductive plate extends away from the surface of the carrier unit. Therefore, the heat conductive plate has a greater surface area contacting with air so that the heat conductive plate has a better heat dissipating efficiency.

In addition, adjacent first extending sections do not contact with each other and intervals are kept therebetween. Therefore, the heat conductive plate has a greater surface area and a better heat dissipating efficiency.

In addition, the distance between the two first extending sections of the two extending units of the heat conductive plate corresponds to the width of the heat pipe, and the distance between the two second extending sections and the surface of the carrier unit corresponds to the thickness of the heat pipe. Therefore, the heat conductive plate has a better heat dissipating efficiency as well as being capable of fastening the heat pipe.

The embodiments were chosen and described in order to explain the principles of the disclosure and their practical application so as to motivate others skilled in the art to utilize the disclosure and various embodiments and with various modifications as are suited to the particular use that is being contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A heat conductive plate, for thermally contacting with a heat pipe, comprising:
a carrier unit, the heat pipe thermally contacting with a surface of the carrier unit; and
at least one extending unit, disposed on the surface of the carrier unit, the at least one extending unit comprising a first extending section extending away from the surface of the carrier unit.

2. The heat conductive plate according to claim 1, wherein the at least one extending unit further comprises a second extending section, the second extending section extends from the first extending section, and the extending direction of the second extending section is substantially parallel to the surface.

3. The heat conductive plate according to claim 2, wherein the extending direction of the first extending section and the extending direction of the second extending section are substantially orthogonal.

4. The heat conductive plate according to claim 2, wherein the quantity of the at least one extending unit is two, the two extending units are disposed on two opposite sides of the carrier unit, the distance between the two first extending sections of the two extending units corresponds to the width of the heat pipe, and the distance from the two second extending sections of the two extending units to the surface of the carrier unit corresponds to the thickness of the heat pipe.

5. The heat conductive plate according to claim 1, wherein the quantity of the at least one extending unit is plural, the extending units are arranged along two opposite sides of the carrier unit, the first extending sections of each two adjacent ones of the at least one extending unit do not contact with each other.

6. The heat conductive plate according to claim 1, wherein the carrier unit and the at least one extending unit are integrally formed with each other.

7. A heat dissipating module, for dissipating heat generated by a heat source, the heat dissipating module comprising:
a heat pipe, and a heat conductive plate, comprising:
a carrier unit, having a first surface and a second surface opposite to each other, the first surface thermally contacting with the heat pipe, and the second surface thermally contacting with the heat source; and
at least one extending unit, disposed on the first surface of the carrier unit, the at least one extending unit comprising a first extending section extending away from the first surface of the carrier unit.

8. The heat dissipating module according to claim 7, wherein the at least one extending unit further comprises a second extending section, the second extending section extends from the first extending section, and the extending direction of the second extending section is substantially parallel to the surface.

9. The heat dissipating module according to claim 8, wherein the extending direction of the first extending section and the extending direction of the second extending section are substantially orthogonal.

10. The heat dissipating module according to claim 8, wherein the quantity of the at least one extending unit is two, the two extending units are disposed on two opposite sides of the carrier unit, the distance between the two first extending sections of the two extending units corresponds to the width of the heat pipe, and the distance from the two second extending sections of the two extending units to the surface of the carrier unit corresponds to the thickness of the heat pipe.
